(19) United States
(12) Patent Application Publication
(10) Pub. No.: US 2025/0341557 A1
(43) Pub. Date: Nov. 6, 2025

(54) TEST DEVICE, TEST SYSTEM AND OPERATING METHOD OF TEST DEVICE

(71) Applicant: Samsung Electronics Co., Ltd., Suwon-si (KR)

(72) Inventors: Junsik PARK, Suwon-si (KR); Youngmin KU, Suwon-si (KR); Namsu KIM, Suwon-si (KR); Heesu KIM, Suwon-si (KR); Chunghyun RYU, Suwon-si (KR)

(73) Assignee: Samsung Electronics Co., Ltd., Suwon-si (KR)

(21) Appl. No.: 18/987,180

(22) Filed: Dec. 19, 2024

(30) Foreign Application Priority Data
May 3, 2024 (KR) 10-2024-0059411

(51) Int. Cl. G01R 31/00; G01R 31/28

(52) U.S. Cl. CPC G01R 31/002; G01R 31/2839

(57) ABSTRACT

A test device includes an electrostatic discharge test circuit electrically connected to at least one subject, a frame configured to accommodate the at least one subject and the electrostatic discharge test circuit, a transport device configured to move, the movement of the transport device causing the frame to move, and processing circuitry configured to, control the movement of the transport device such that the electrostatic discharge test circuit becomes electrically connected to a power supply device based on a position of the transport device, and control the movement of the transport device such that the at least one subject becomes electrically connected to a host device based on the position of the transport device.

### CROSS-REFERENCE TO RELATED APPLICATION

This U.S. non-provisional application is based on and claims the benefit of priority under 35 U.S.C. § 119 to Korean Patent Application No. 10-2024-0059411, filed on May 3, 2024, in the Korean Intellectual Property Office, the disclosure of which is incorporated by reference herein in its entirety.

### BACKGROUND

Some example embodiments of the inventive concepts relate to a test device, and more particularly, to a test device for testing the susceptibility of a test subject to electrostatic discharge (ESD), a system including the test device, and/or a method of operating the test device, etc.

A semiconductor integrated circuit may be shipped as a product after a wafer-level process, a package-level process, and/or a post-package level process are performed. The semiconductor integrated circuit may be mounted in a semiconductor device, such as a solid state drive (SSD), etc., and may perform its unique function.

When the semiconductor device (e.g., SSD) including the semiconductor integrated circuit is mounted on another electronic device (e.g., a personal computer (PC), etc.) by a person, charges accumulated in the human body (e.g., static electricity) may be discharged to the electronic device through the semiconductor device. When external charges are discharged to the electronic device through the semiconductor device, the semiconductor device may be damaged. Therefore, to ensure the performance of the semiconductor device, an electrostatic discharge (ESD) test may be conducted to test the electromagnetic susceptibility of the semiconductor device.

### SUMMARY

Some example embodiments of the inventive concepts provide a test device capable of testing the susceptibility of a semiconductor device and a subject to electrostatic discharge (ESD), a system including the test device, and/or a method of operating the test device, etc.

According to at least one example embodiment of the inventive concepts, there is provided a test device including an electrostatic discharge test circuit electrically connected to at least one subject, a frame configured to accommodate the at least one subject and the electrostatic discharge test circuit, and processing circuitry configured to, control the movement of the transport device such that the electrostatic discharge test circuit becomes electrically connected to a power supply device based on a position of the transport device, and control the movement of the transport device such that the at least one subject becomes electrically connected to a host device based on the position of the transport device.

According to at least one example embodiment of the inventive concepts, there is provided a test system including an electrostatic discharge test circuit electrically connected to at least one subject, a frame configured to accommodate the at least one subject and the electrostatic discharge test circuit, processing circuitry configured to control the movement of the transport device, a power supply device configured to selectively electrically connect to the electrostatic discharge test circuit based on a position of the transport device, the power supply device being configured to transfer electrical charge to the at least one subject and the electrostatic discharge test circuit, and a host device configured to selectively electrically connect to the at least one subject based on the position of the transport device.

According to at least one example embodiment of the inventive concepts, there is provided a method of operating a test device, the method including in response to at least one subject being accommodated in a frame and being electrically connected to an electrostatic discharge test circuit, moving the frame in a first direction using a transport device, and moving the frame in a second direction using transport device.

### BRIEF DESCRIPTION OF THE DRAWINGS

Some example embodiments will be more clearly understood from the following detailed description taken in conjunction with the accompanying drawings in which:

FIG. 1 is a block diagram of a test system according to at least one example embodiment;

FIG. 2 shows an implementation example of a test system according to at least one example embodiment;

FIG. 3 is a block diagram of an example of an electric circuit included in a test device, according to at least one example embodiment;

FIG. 4 is a diagram showing charge flow when a test device moves in a first direction and comes in contact with a power supply device through a node between a first resistance circuit and a first capacitor circuit of a first discharge circuit, according to at least one example embodiment;

FIG. 5 is a diagram showing charge flow when a test device moves in a first direction and comes in contact with a power supply device through a node between a second resistance circuit and a second capacitor circuit of a second discharge circuit, according to at least one example embodiment;

FIG. 6 is a diagram showing charge flow when a test device moves in a first direction and comes in contact with a power supply device through a node between a first resistance circuit of a first discharge circuit and a subject, according to at least one example embodiment;

FIG. 7 is a diagram showing charge flow when a test device moves in a first direction and comes in contact with a power supply device through a node between a second resistance circuit of a second discharge circuit and a subject, according to at least one example embodiment;

FIG. 8 is a diagram showing charge flow when a test device moves in a second direction and comes in contact with a host device, according to at least one example embodiment;

FIG. 9 is a flowchart of a method of operating a test device, according to at least one example embodiment; and

FIG. 10 is a flowchart of an additional method of operating a test device, according to at least one example embodiment.

### DETAILED DESCRIPTION

Hereinafter, one or more example embodiments are described in detail with reference to the attached drawings.

In conventional ESD testing of semiconductor devices, a person (e.g., a user, a technician, an operator, etc.) may repeat the operation of mounting the semiconductor device on the electronic device one or more times. However, when a person manually repeats the mounting operation, it may be time-consuming and/or inefficient. In addition, because electrical charge needs to be discharged to the semiconductor device from the human body in order to perform the ESD testing, the person's body has to be charged to a high voltage before each test, which may lead to dangerous situations. Therefore, methods of testing ESD of semiconductor devices without human involvement are desired.

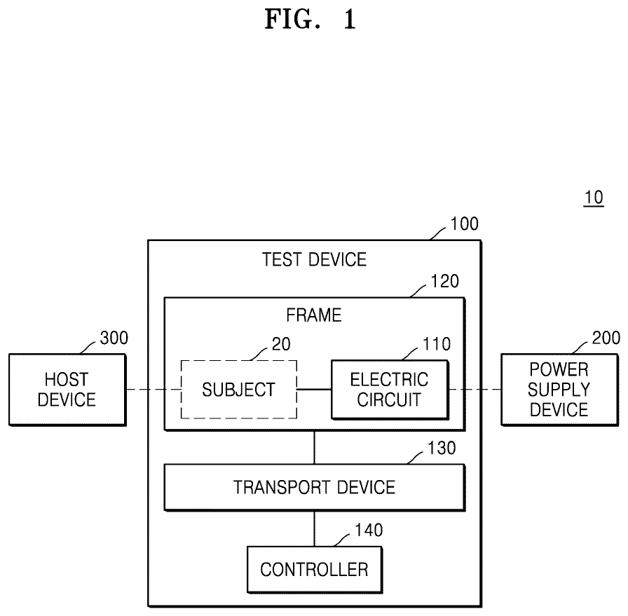

FIG. 1 is a block diagram of a test system according to at least one example embodiment.

Referring to FIG. 1, a test system 10 may include a test device 100, a power supply device 200, and/or a host device 300, etc., but the example embodiments are not limited thereto, and for example, the test system 10 may include a greater or lesser number of constituent components.

The test system 10 may be a system configured to conduct at least one test on at least one subject 20. In more detail, the test system 10 may be a system configured to conduct at least one electrostatic discharge (ESD) test designed to test the electromagnetic susceptibility of the subject 20. For example, the test system 10 may be a system simulating a situation in which, for example, a person becomes electrostatically charged (e.g., charged with static electricity, etc.) during daily activities (e.g., walking, moving their limbs, etc.) and then mounts, handles, and/or installs the subject 20 on and/or into the host device 300, the electric and/or electrostatic charges charged to the person are discharged to the host device 300 through the subject 20. However, the example embodiments are not limited thereto, and for example, the test system 10 may simulate a situation where an ESD event occurs when the subject 20 comes into contact with the host device 300 with or without involvement of a human, etc. As a determination as to whether any damage has occurred to the subject 20 is made using the test system 10 after the charges are discharged through the subject 20, the electromagnetic susceptibility of the subject 20 may be checked and/or determined.

The subject 20 may be a device on which the ESD test is performed by the test system 10. In at least one example embodiment, the subject 20 may be a semiconductor device including a semiconductor integrated circuit and may be, for example, any one of solid state drive (SSD), a dynamic random access memory (DRAM) module, etc., but is not limited thereto. Additionally, according to some example embodiments, the subject 20 may be an electronic device which may be susceptible to damage due to ESD, such as a television, a smartphone, a tablet, a personal computer, a laptop computer, a server, etc.

The test device 100 (e.g., the testing device, etc.) may accommodate the subject 20 (e.g., the device to be tested, the test subject, etc.) and may move the subject 20 in order to enable the discharge of static electricity through and/or to the subject 20. FIG. 1 shows that the subject 20 is inside the test device 100. However, the example embodiments are not limited thereto, and for example, the subject 20 may be accommodated by (e.g., in electrical and/or electrostatic communication with) the test device 100 and the subject 20 does not need to be inside the test device 100, etc.

In at least one example embodiment, the test device 100 may include an electric circuit 110 (e.g., an electrostatic discharge test circuit, etc.), a frame 120, a transport device 130, and/or a controller 140, etc., but is not limited thereto.

The electric circuit 110 (e.g., electrostatic discharge test circuit, etc.) may be at least one circuit configured to discharge static electricity to and/or into the subject 20. The electric circuit 110 may be electrically connected to the subject 20. The electric circuit 110 may cause static electricity to be discharged to, into, and/or through the subject 20 as the charges are charged to and/or in the electric circuit 110 first and then the charged charges are discharged to the subject 20. In other words, the electric circuit 110 may generate electricity, static electricity, and/or electrostatic charge, etc., and may transfer, transmit and/or provide the generated electricity, static electricity, and/or electrostatic charge to the subject 20.

In at least one example embodiment, the electric circuit 110 may have an impedance value corresponding to a human model thereby simulating an environment where static electricity is generated by the human body and discharged through (and/or transferred to, transmitted to, etc.) the subject 20, etc. The electric circuit 110 may have an impedance value corresponding to the impedance value of a human holding and/or contacting the subject 20 with their hands, but the example embodiments are not limited thereto. However, the example embodiments are not limited thereto, and other impedance values may be used, and for example, may be determined based on experiential values, etc.

The electric circuit 110 may be implemented as an RC (e.g., Resistor-Capacitor) circuit, but is not limited thereto. The impedance value of the RC circuit may be set by, for example, measuring the impedance of a human holding and/or contacting the subject 20 with their hands and/or performing desired, normal, and/or expected tasks with the subject 20, and then modeling the measured impedance value as a resistor and a capacitor in a desired and/or preset frequency band (e.g., a frequency band of 10 MHz, etc.), but the example embodiments are not limited thereto.

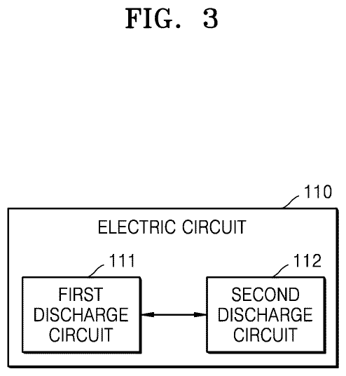

The electric circuit 110 may include one or more discharge circuits (e.g., discharging circuitry, etc.), but is not limited thereto. Each of the discharge circuits may be an RC circuit, but is not limited thereto. The discharge circuits may include a resistance circuit including one or more resistors and/or a capacitor circuit including one or more capacitors, etc., but are not limited thereto. The detailed structure and operation of the electric circuit 110 are described with reference to FIG. 3 below.

The electric circuit 110 may be in contact with, electrically connected to, and/or in electrical communication with the power supply device 200 as the test device 100 moves, but is not limited thereto. The electric circuit 110 may be charged as it contacts, is electrically connected to, and/or in electrical communication with the power supply device 200.

The power supply device 200 may be a device for generating and/or applying a voltage to the electric circuit 110. The power supply device 200 may charge the electric circuit 110 and, more particularly, charge at least one capacitor included in the electric circuit 110. The charging of the electric circuit 110 by the power supply device 200 may correspond to a situation where, for example, a person becomes electrically and/or electrostatically charged during daily activities (e.g., walking, moving their limbs, etc.), but the example embodiments are not limited thereto.

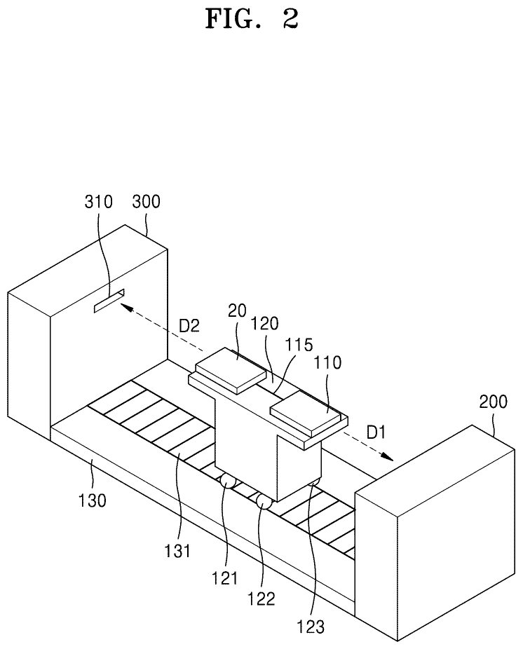

The frame 120 may accommodate, store, and/or receive the subject 20 and/or the electric circuit 110, etc. The frame 120 may accommodate, store, and/or receive the subject 20 and/or the electric circuit 110 and may have a structure movable by the transport device 130, etc., but is not limited thereto. A structure example of the frame 120 is described below with reference to FIG. 2.

FIG. 1 shows that the subject 20 and the electric circuit 110 are inside the frame 120. However, the example embodiments are not limited thereto, and for example, the subject 20 and the electric circuit 110 may be accommodated by the frame 120 and/or manipulatable by the transport device 130, and the example embodiments do not require the subject 20 and the electric circuit 110 to be included in the frame 120, etc.

The transport device 130 may move the frame 120 in a first direction and/or a second direction, etc., but the example embodiments are not limited thereto, and for example, the transport device 130 may move the frame 120 in a third direction, etc. The first direction may be the direction in which the power supply device 200 is located, and the transport device 130 may make and/or cause the electric circuit 110 to contact the power supply device 200 by moving the frame 120 in the first direction, etc. The second direction may be the direction in which the host device 300 is located, and the transport device 130 may make and/or cause the subject 20 to contact the host device 300 by moving the frame 120 in the second direction, etc. In at least one example embodiment, the first direction may be opposite to the second direction, but is not limited thereto.

The transport device 130 may have a structure in which the frame 120 is transported in the first direction and the second direction, but is not limited thereto. A structure example of the transport device 130 is described below with reference to FIG. 2.

The controller 140 may control overall operations of the test device 100, etc. According to some example embodiments, the controller 140, etc., may be implemented as processing circuitry. The processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

In more detail, the controller 140 may control the transport device 130, using for example at least one control signal, etc., such that the frame 120 may be transported in the first direction and/or the second direction, etc.

In at least one example embodiment, the controller 140 may control the transport device 130 such that the frame 120 is moved in the first direction and the electric circuit 110 comes into contact with the power supply device 200, but the example embodiments are not limited thereto. In this case, when the electric circuit 110 contacts the power supply device 200, the electric circuit 110 may be charged with charges by the power supply device 200 (e.g., the electric circuit 110 may become charged and/or enter a charged state, etc.). In addition, when the electric circuit 110 contacts the power supply device 200, a capacitor (e.g., a parasitic capacitor, etc.) inside and/or included in the subject 20 may also be charged through the electric circuit 110 (e.g., the capacitor may become charged and/or enter a charged state, etc.).

In at least one example embodiment, the controller 140 may control the transport device 130 such that the frame 102 is moved in the second direction to make and/or cause the subject 20 to contact the host device 300, but is not limited thereto. In this case, when the subject 20 contacts the host device 300, the charges stored in the electric circuit 110 may be discharged (and/or transferred, transmitted, etc.) to the host device 300 through the subject 20, etc., but the example embodiments are not limited thereto. In addition, when the subject 20 contacts the host device 300, the capacitor (e.g., the parasitic capacitor, etc.) inside and/or included in the subject 20 may also be discharged.

In at least one example embodiment, the controller 140 may control the transport device 130 such that the transport device 130 moves the frame 120 in the first direction to make the electric circuit 110 contact the power supply device 200 and then moves the frame 120 in the second direction to make the subject 20 contact the host device 300, but the example embodiments are not limited thereto. To this end, the controller 140 may be configured such that charges are charged to the electric circuit 110 (e.g., the electric circuit 110 becomes charged, etc.) and then the charges charged to the electric circuit 110 are discharged to the host device 300 through the subject 20, etc., but is not limited thereto.

Also, in at least one example embodiment, the controller 140 may control the transport device 130 to make the frame 120 reciprocate between the power supply device 200 and the host device 300 for a desired and/or preset reference number of times. That is, the controller 140 may repeat the operation, in which the charges are charged to the electric circuit 110 and the charges are discharged to the host device 300 through the subject 20, for the reference number of times. To this end, static electricity may be repeatedly discharged through the subject 20.

The host device 300 may be equipped with the subject 20. In at least one example embodiment, the host device 300 may be an electronic device equipped with a semiconductor device and may be, for example, any one of a personal computer (PC), a laptop, a server, a smartphone, a tablet, etc., but is not limited thereto.

The host device 300 may contact the subject 20 as the frame 120 is moved by the transport device 130 in the second direction, etc. When the host device 300 contacts the subject 20, the charges charged to and/or in the electric circuit 110 and/or the subject 20 may be discharged to (e.g., transferred to, transmitted to) the host device 300. The discharge of the charged charges to the host device 300 may correspond to a situation where, when a charged person mounts and/or installs the subject 20 to the host device 300, the charges on and/or stored in the person are discharged to (e.g., transferred to, transmitted to) the host device 300 through the subject 20.

After the charges charged to, transferred to, and/or stored in the electric circuit 110 and/or the subject 20 are discharged to, transferred to, and/or transmitted to the host device 300, the host device 300 may determine whether the subject 20 contacting and/or installed in the host device 300 is normally detected, thus determining whether the subject 20 is damaged by the discharge. In other words, the host device 300 may perform a diagnostic test (e.g., a SSD diagnostic test, a memory module diagnostic test, etc.) on the subject 20 to determine whether the subject 20 is operating and/or functioning correctly, but the example embodiments are not limited thereto. However, this is only an example, and a separate verification device may be used to determine whether the subject 20 is damaged by the discharge based on the results of the verification test and/or diagnostic test, etc. When a separate verification device (not shown) is used, data may be input to the subject 20 by, for example, using the verification device, and a determination as to whether data output by the subject 20 matches a desired value (e.g., the original data stored in the subject 20, etc.) is made; thus, the verification device may determine whether there is any damage to the subject 20, but the example embodiments are not limited thereto. As another example, the verification device may be used to determine whether there is any damage to the subject 20 by checking whether initial setting values in the subject 20 have changed after the ESD test has been performed, etc.

When the test device 100 described above is used, the susceptibility of the subject 20 to ESD may be tested and/or automatically tested by moving the subject 20 in the first direction and/or the second direction, etc., but is not limited thereto.

FIG. 2 shows an implementation example of a test system according to at least one example embodiment.

Referring to FIG. 2, the test system 10 according to at least one example embodiment may include the test device 100, the power supply device 200, and/or the host device 300, etc., but the example embodiments are not limited thereto.

The test device 100 may include the electric circuit 110, the frame 120, and/or the transport device 130, etc., but is not limited thereto. Although not shown in FIG. 2, the test device 100 may also include the controller 140, and the controller 140 may be included inside the frame 120 and/or the transport device 130, but is not limited thereto.

In FIG. 2, the electric circuit 110 may be accommodated in the upper portion of the frame 120. However, this is only an example, and the electric circuit 110 may be accommodated in other areas of the frame 120. The electric circuit 110 may be connected to the subject 20 through at least one wire 115, etc. When the electric circuit 110 is accommodated in the upper portion of the frame 120, the electric circuit 110 may be arranged such that at least one node contacting the power supply device 200 and/or a wire connected to the node contacting the power supply device 200 may be oriented towards the power supply device 200.

In FIG. 2, the subject 20 may be accommodated in the upper portion of the frame 120, but is not limited thereto. The subject 20 may be accommodated in the upper portion of the frame 120 to allow a user to easily change the subject 20, but the example embodiments are not limited thereto. The subject 20 may be connected to the electric circuit 110 through the wire 115, but is not limited thereto, and for example, the subject 20 may receive charges from the electric circuit 110 without a wire (e.g., through air, etc.). When the subject 20 is accommodated in the upper portion of the frame 120, the subject 20 may be arranged such that a pin faces the host device 300, but the example embodiments are not limited thereto.

In FIG. 2, the frame 120 may have a structure in which the upper portion of the frame 120 is wider than the lower portion thereof, but is not limited thereto. The above structure is configured so that, when the frame 120 is moved by the transport device 130 in a first direction D1 and a second direction D2, the electric circuit 110 and the subject 20 accommodated in the upper portion of the frame 120 may contact and/or smoothly contact the power supply device 200 and the host device 300, respectively. However, the example embodiments are not limited thereto and the structure of the frame 120 may have any structure that allows the electric circuit 110 and the subject 20 to contact and/or smoothly contact the power supply device 200 and the host device 300, respectively. For example, while the at least one example embodiment of FIG. 2 is depicted as having a linear shape and/or moving in a linear direction, the example embodiments are not limited thereto, and for example, the frame 120 may have a circular shape and the frame 120 may rotate between the power supply device 200 and the host device 300, etc.

In FIG. 2, the frame 120 may include a plurality of wheels 121 to 123, but is not limited thereto, and for example, the frame 120 may include other devices to facilitate movement to the power supply device 200 and/or the host device 300, such as one or more rollers, the frame 120 may be arranged on a conveyor belt, the frame 120 may rotate, etc. For example, as the wheels 121 to 123 are rotated by the transport device 130, the frame 120 may be moved in the first direction D1 and/or the second direction D2, etc.

In FIG. 2, the transport device 130 may be arranged on the lower portion of the frame 120, but is not limited thereto. The transport device 130 may include at least one rail 131, etc. The transport device 130 may supply and/or provide a path through which the frame 120 is moved along the rail 131, but is not limited thereto. In addition, pressure may be applied to the frame 120 by the transport device 130, and the transport device 130 may allow the frame 120 to move along the rail 131, etc. However, the example embodiments are not limited thereto. Additionally, the transport device 130 may include a motor connected to the plurality of wheels 121 to 123 to facilitate the movement of the frame 120 along the rail 131, but is not limited thereto. The transport device 130 may have any structure that allows the frame 120 to move in the first direction D1 and/or the second direction D2, etc.

The power supply device 200 may be located in the first direction D1 of the frame 120. As the frame 120 is moved in the first direction D1, the power supply device 200 may contact and/or may electrically communicate with the electric circuit 110. The power supply device 200 may include at least one power supply terminal (not shown) at a location at which the power supply device 200 contacts and/or electrically communicates with the electric circuit 110, but is not limited thereto.

The host device 300 may be located in the second direction D2 of the frame 120, but is not limited thereto. As the frame 120 is moved in the second direction D2, the host device 300 may contact and/or electrically communicate with the subject 20. The host device 300 may include at least one connector 310 at a location at which the host device 300 contacts and/or electrically communicates with the subject 20, but the example embodiments are not limited thereto.

FIG. 3 is a block diagram of an example of an electric circuit included in a test device, according to at least one example embodiment.

Referring to FIG. 3, the electric circuit 110 of the test device 100 according to at least one example embodiment may include a plurality of discharge circuits, e.g., a first discharge circuit 111 and a second discharge circuit 112, but the example embodiments are not limited thereto. While FIG. 3 shows an example in which the electric circuit 110 includes two discharge circuits, but the example embodiments are not limited thereto, and for example, may include a greater or lesser number of discharge circuits. For example, the electric circuit 110 may include one discharge circuit or three or more discharge circuits. However, an example in which the electric circuit 110 includes two discharge circuits, for example, a first discharge circuit 111 and a second discharge circuit 112, is mainly described below.

The first discharge circuit 111 may be an RC circuit including at least one first resistance circuit and at least one first capacitor circuit, but is not limited thereto. The second discharge circuit 112 may be an RC circuit including at least one second resistance circuit and at least one second capacitor circuit, but is not limited thereto. In this case, each of the first resistance circuit and the second resistance circuit may include one or more resistors connected in series and/or parallel and thus may have desired and/or preset resistance values. In addition, each of the first capacitor circuit and the second capacitor circuit may include one or more capacitors connected in series and/or parallel and thus have desired and/or preset capacitance values.

The first discharge circuit 111 may have a first impedance value (e.g., a desired first impedance value, etc.). The second discharge circuit 112 may have a second impedance value (e.g., a desired second impedance value, etc.). In this case, the first impedance value may be different from the second impedance value, but is not limited thereto. For example, compared to the second impedance value, the first impedance value may have a relatively great (and/or higher) resistance value and a relatively low (e.g., lower) capacitance value, but is not limited thereto. As the first discharge circuit 111 and the second discharge circuit 112 have different impedance values, the susceptibility of the subject 20 to ESD may be tested by considering that the impedance value of the person holding and/or contacting the subject 20 with their hands changes depending on the type (e.g., material type, composition, etc.) of the subject 20, etc.

In this case, depending on the type of the subject 20, any one of the first discharge circuit 111 and the second discharge circuit 112 may only be used for the susceptibility test of the subject 20 regarding ESD, but the example embodiments are not limited thereto. For example, when the subject 20 does not have a case, the test may be conducted by connecting the first discharge circuit 111 to the subject 20. On the contrary, when the subject 20 has a case, the test may be conducted by connecting the second discharge circuit 112 to the subject 20, etc.

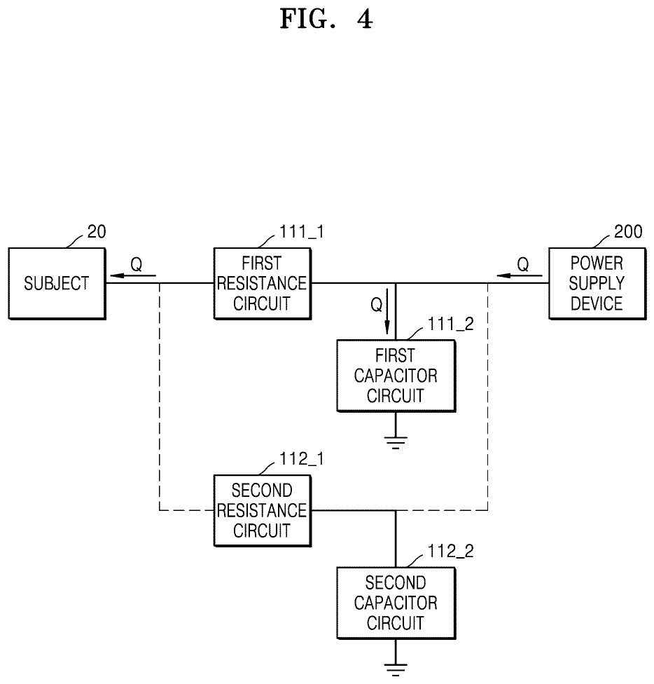

The more detailed connection of the electric circuit 110 and the charge flow (e.g., flow of charge, etc.) when the electric circuit 110 contacts the power supply device 200 may be described below in more detail with reference to FIG. 4.

FIG. 4 is a diagram showing charge flow when a test device moves in a first direction and comes in contact with a power supply device through a node between a first resistance circuit and a first capacitor circuit of a first discharge circuit, according to at least one example embodiment.

The first discharge circuit 111 and the second discharge circuit 112 shown in FIGS. 4 to 7 may have a common structure described below, but the example embodiments are not limited thereto.

According to at least one example embodiment, the first discharge circuit 111 may include a first resistance circuit 111_1 and a first capacitor circuit 111_2, etc., but is not limited thereto.

The first resistance circuit 111_1 may be selectively connected to the subject 20 through an end portion of the first resistance circuit 111_1. For example, when the first discharge circuit 111 is used for the test of the subject 20, the first resistance circuit 111_1 may be connected (e.g., electrically connected, physically connected, etc.) to the subject 20 through an end portion (e.g., a first end, etc.) of the first resistance circuit 111_1. The first resistance circuit 111_1 may be connected to the first capacitor circuit 111_2 through the other end portion (e.g., a second end, etc.) of the first resistance circuit 111_1, but is not limited thereto.

The first capacitor circuit 1112 may be connected between the first resistance circuit 111_1 and a ground node, but is not limited thereto. An end portion (e.g., a first end, etc.) of the first capacitor circuit 111_2 may be connected to the other end portion (e.g., second end) of the first resistance circuit 111_1. The other end portion (e.g., second end) of the first capacitor circuit 111_2 may be connected to the ground node.

The second discharge circuit 112 may include a second resistance circuit 112_1 and a second capacitor circuit 112_2, but is not limited thereto.

An end portion (e.g., first end, etc.) of the second resistance circuit 112_1 may be selectively connected to the subject 20. For example, when the second discharge circuit 112 is used for the test of the subject 20, an end portion (e.g., first end) of the second resistance circuit 112_1 may be connected to the subject 20. The other end portion (e.g., second end, etc.) of the second resistance circuit 112_1 may be connected to the second capacitor circuit 1122, but is not limited thereto.

The second capacitor circuit 112_2 may be connected between the second resistance circuit 112_1 and the ground node, but is not limited thereto. An end portion (e.g., first end) of the second capacitor circuit 112_2 may be connected to the other end portion (e.g., second end) of the second resistance circuit 112_1, but is not limited thereto. The other end portion (e.g., second end) of the second capacitor circuit 1122 may be connected to the ground node, but is not limited thereto.

The common structure of the first discharge circuit 111 and the second discharge circuit 112 is as described above, and hereinafter, the features of the first discharge circuit 111 and the second discharge circuit 112 are mainly described with reference to FIG. 4.

Referring to FIG. 4, the first discharge circuit 111 may be used for the test of the subject 20, and the first discharge circuit 111 contacts and/or electrically connects to the power supply device 200 through the node between the first resistance circuit 111_1 and the first capacitor circuit 111_2, but is not limited thereto.

In the example of FIG. 4, because the first discharge circuit 111 is used for the test (e.g., a first test, a first test type, etc.) of the subject 20, an end portion of first resistance circuit 111_1 may be connected to and/or electrically connected to the subject 20 (as indicated by a solid line), but the example embodiments are not limited thereto. On the contrary, because the second discharge circuit 112 is not used for the test (e.g., the first test) of the subject 20, an end portion of the second resistance circuit 1121 may not be connected to the subject 20 (as indicated by a dashed line), but the example embodiments are not limited thereto.

In addition, because the first discharge circuit 111 is used for the test of the subject 20, when the frame 120 is moved in the first direction, the node between the first resistance circuit 111_1 and the second capacitor circuit 111_2 may be connected to the power supply device 200 (as indicated by a solid line). Conversely, because the second discharge circuit 112 is not used for the test of the subject 20, although the frame 120 is moved in the first direction, the node between the second resistance circuit 112_1 and the second capacitor circuit 1122 may not be connected to the power supply device 200 (as indicated by a dashed line).

In this case, some of the charges Q from the power supply device 200 may be charged to (e.g., may charge) the first capacitor circuit 111_2. In addition, the remaining charges Q from the power supply device 200 may be charged to (e.g., may charge) a capacitor inside the subject 20 through the first resistance circuit 111_1, but the example embodiments are not limited thereto.

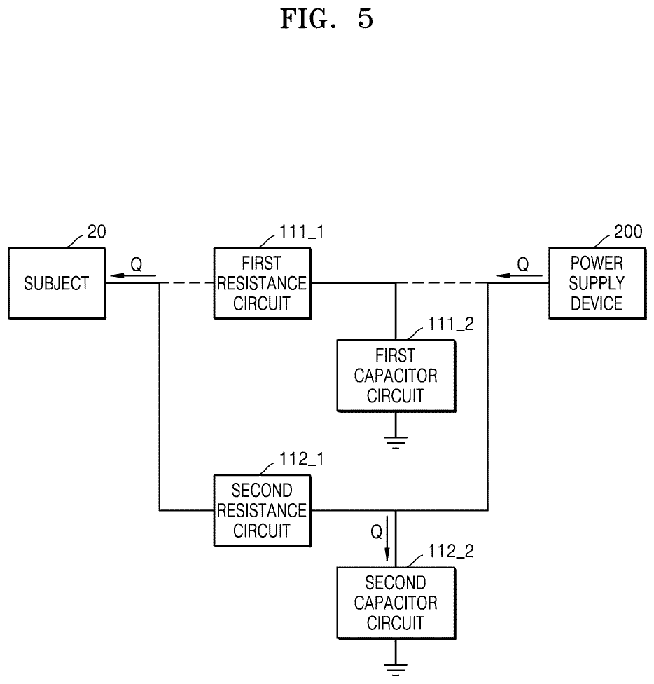

FIG. 5 is a diagram showing charge flow when a test device moves in a first direction and comes in contact with and/or electrically connects with a power supply device through a node between a second resistance circuit and a second capacitor circuit of a second discharge circuit, according to at least one example embodiment.

Referring to FIG. 5, the second discharge circuit 112 may be used for the test (e.g., a second test, a second test type, etc.) of the subject 20, and the second discharge circuit 112 contacts and/or electrically connects with the power supply device 200 through the node between the second resistance circuit 112_1 and the second capacitor circuit 112_2, but the example embodiments are not limited thereto.

In the example of FIG. 5, because the second discharge circuit 112 is used for the test (e.g., second test) of the subject 20, an end portion of the second resistance circuit 1121 may be connected to and/or electrically connected to the subject 20 (as indicated by a solid line). On the contrary, because the first discharge circuit 111 is not used for the test (e.g., the second test) of the subject 20, an end portion of the first resistance circuit 111_1 may not be connected to and/or may not be electrically connected to the subject 20 (as indicated by a dashed line).

In addition, because the second discharge circuit 112 is used for the test (e.g., second test) of the subject 20, when the frame 120 is moved in the first direction, the node between the second resistance circuit 112_1 and the second capacitor circuit 112_2 may be connected to and/or electrically connected to the power supply device 200 (as indicated by a solid line), but the example embodiments are not limited thereto. Conversely, because the first discharge circuit 111 is not used for the test of the subject 20, although the frame 120 is moved in the first direction, the node between the first resistance circuit 111_1 and the first capacitor circuit 111_2 may not be connected to and/or may not be electrically connected to the power supply device 200 (as indicated by a dashed line), but the example embodiments are not limited thereto.

In this case, some of the charges Q from the power supply device 200 may be charged to (e.g., may charge, etc.) the second capacitor circuit 1122, etc. In addition, the remaining charges Q from the power supply device 200 may be charged to (e.g., may charge) a capacitor inside the subject 20 through the second resistance circuit 112_1, etc.

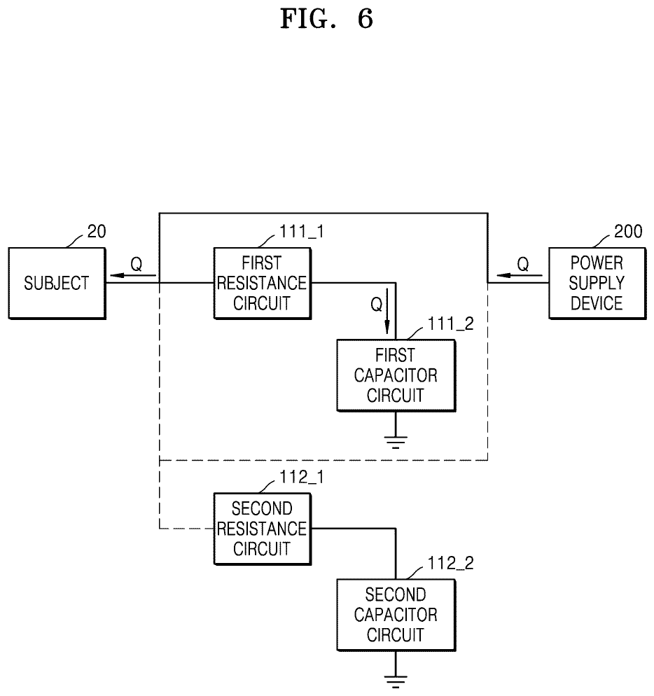

FIG. 6 is a diagram showing charge flow when a test device moves in a first direction and comes in contact with a power supply device through a node between a first resistance circuit of a first discharge circuit and a subject, according to at least one example embodiment.

Referring to FIG. 6, the first discharge circuit 111 may be used for the test (e.g., first test, first test type, etc.) of the subject 20, and the first discharge circuit 111 contacts and/or electrically connects with the power supply device 200 through the node between the first resistance circuit 111_1 and the subject 20, but is not limited thereto.

In this case, when the first discharge circuit 111 is used for the test of the subject 20, the first discharge circuit 111 may contact and/or electrically connect with the power supply device 200 through the node between the first resistance circuit 111_1 and the subject 20 as shown in FIG. 6, or the first discharge circuit 111 may contact and/or electrically connect with the power supply device 200 through the node between the first resistance circuit 111_1 and the first capacitor circuit 111_2 as shown in FIG. 4, but the example embodiments are not limited thereto. In other words, the first discharge circuit 111 may contact the power supply circuit 200 through any one of the node between the first resistance circuit 111_1 and the subject 20 or the node between the first resistance circuit 111_1 and the first capacitor circuit 111_2, but is not limited thereto.

In FIG. 6, because the first discharge circuit 111 is used for the test of the subject 20, an end portion of first resistance circuit 111_1 may be connected to and/or electrically connect to the subject 20 (as indicated by a solid line). On the contrary, because the second discharge circuit 112 is not used for the test of the subject 20, an end portion of the second resistance circuit 112_1 may not be connected to and/or may not be electrically connected to the subject 20 (as indicated by a dashed line).

In addition, because the first discharge circuit 111 is used for the test of the subject 20, when the frame 120 is moved in the first direction, the node between the first resistance circuit 111_1 and the subject 20 may be connected to and/or electrically connected to the power supply device 200 (as indicated by a solid line), but the example embodiments are not limited thereto. Conversely, because the second discharge circuit 112 is not used for the test of the subject 20, although the frame 120 is moved in the first direction, the node between the second resistance circuit 112_1 and the subject 20 may not be connected to and/or may not be electrically connected to the power supply device 200 (as indicated by a dashed line), but the example embodiments are not limited thereto.

In this case, some of the charges Q from the power supply device 200 may be charged to (e.g., may charge, etc.) the first capacitor circuit 111_2 through the first resistance circuit 111_1. Also, the remaining charges Q from the power supply device 200 may be charged to (e.g., may charge, etc.) a capacitor inside the subject 20, but is not limited thereto.

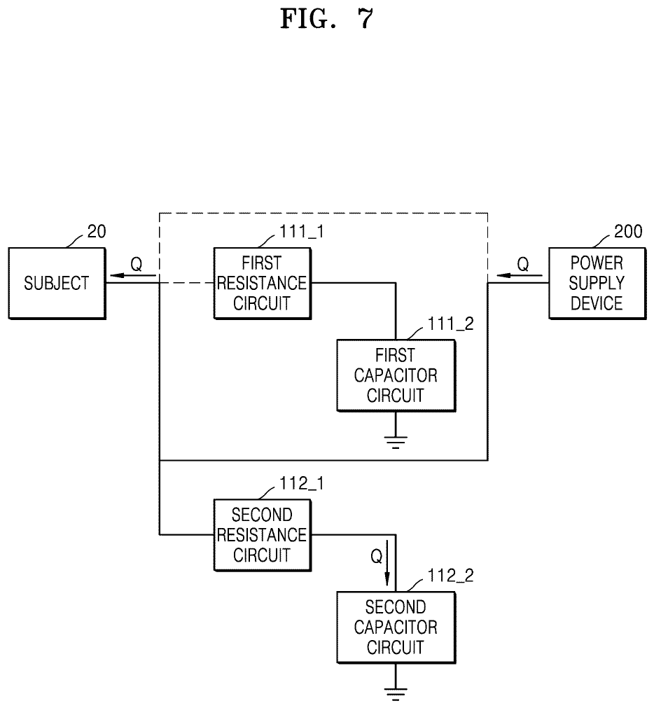

FIG. 7 is a diagram showing charge flow when a test device moves in a first direction and comes in contact with and/or electrically connects to a power supply device through a node between a second resistance circuit of a second discharge circuit and a subject, according to at least one example embodiment.

Referring to FIG. 7, the second discharge circuit 112 may be used for the test (e.g., second test, second test type, etc.) of the subject 20, and the second discharge circuit 112 contacts and/or electrically connects to the power supply device 200 through the node between the second resistance circuit 112_1 and the subject 20.

In this case, when the second discharge circuit 112 is used for the test of the subject 20, the second discharge circuit 112 may contact and/or may electrically connect to the power supply device 200 through the node between the second resistance circuit 112_1 and the subject 20 as shown in FIG. 6, or the second discharge circuit 112 may contact and/or electrically connect to the power supply device 200 through the node between the second resistance circuit 112_1 and the second capacitor circuit 112_2 as shown in FIG. 5, but the example embodiments are not limited thereto. That is, the second discharge circuit 112 may contact and/or electrically connect to the power supply device 200 through any one of the node between the second resistance circuit 112_1 and the subject 20 and the node between the second resistance circuit 112_1 and the second capacitor circuit 112_2, but is not limited thereto.

In the example of FIG. 7, because the second discharge circuit 112 is used for the test of the subject 20, an end portion of the second resistance circuit 112_1 may be connected to and/or may be electrically connected to the subject 20 (as indicated by a solid line). On the contrary, because the first discharge circuit 111 is not used for the test of the subject 20, an end portion of the first resistance circuit 111_1 may not be connected to and/or may not electrically connect to the subject 20 (as indicated by a dashed line), but the example embodiments are not limited thereto.

In addition, because the second discharge circuit 112 is used for the test of the subject 20, when the frame 120 is moved in the first direction, the node between the second resistance circuit 112_1 and the subject 20 may be connected to and/or may be electrically connected to the power supply device 200 (as indicated by a solid line). Conversely, because the first discharge circuit 111 is not used for the test of the subject 20, although the frame 120 is moved in the first direction, the node between the first resistance circuit 111_1 and the subject 20 may not be connected to and/or may not be electrically connected to the power supply device 200 (as indicated by a dashed line).

In this case, some of the charges Q from the power supply device 200 may be charged to (e.g., may charge) the second capacitor circuit 112_2 through the second resistance circuit 112_1. Also, the remaining charges Q from the power supply device 200 may be charged to (e.g., may charge) a capacitor inside the subject 20, etc.

As described above with reference to FIGS. 4 to 7, by using any one of the first discharge circuit 111 and the second discharge circuit 112, the susceptibility of the subject 20 to ESD may be accurately tested according to the type of the subject 20, but the example embodiments are not limited thereto.

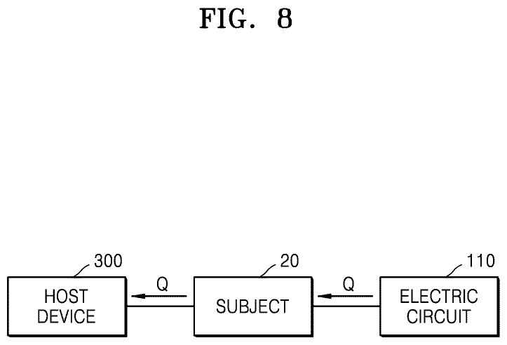

FIG. 8 is a diagram showing charge flow when a test device moves in a second direction and comes in contact with a host device, according to at least one example embodiment.

Referring to FIG. 8, as the frame 120 is moved in the second direction, a flow of charge caused when the subject 20 contacts the host device 300 may be identified.

As the controller 140 controls the transport device 130, when the frame 120 is moved in the second direction, the subject 20 may come into contact with the host device 300. For example, the subject 20 may be mounted on and/or installed on the connector 310 of the host device 300, but is not limited thereto.

When the subject 20 is mounted on the host device 300, the charges Q stored in the capacitor inside the subject 20 may be discharged towards the host device 300. In addition, when the subject 20 is mounted on and/or installed in the host device 300, the charges Q stored in the first capacitor circuit 111_2 and/or the second capacitor circuit 112_2, etc., of the electric circuit 110 may be discharged towards the host device 300 through the subject 20, etc. As described, as the charges Q charged to the electric circuit 110 are discharged to the host device 300 through the subject 20, static electricity may be repeatedly discharged through the subject 20, etc.

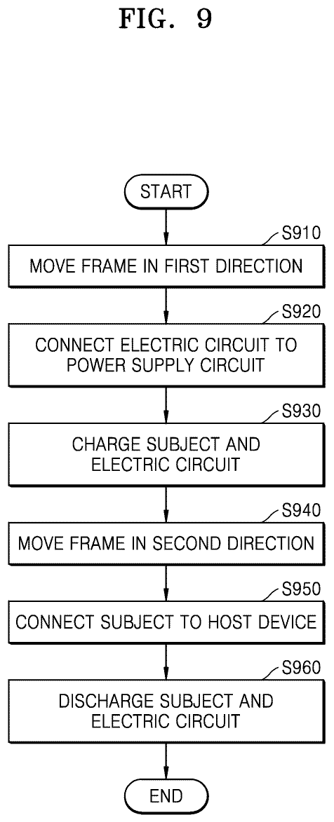

FIG. 9 is a flowchart of a method of operating a test device, according to at least one example embodiment.

Referring to FIG. 9, in operation S910, the test device 100 may move the frame 120 in the first direction, but is not limited thereto. As the controller 140 controls the transport device 130, the test device 100 may move the frame 120 in the first direction, etc.

In operation S920, the electric circuit 110 of the test device 100 may contact the power supply device 200. More specifically, as the frame 120 is moved in the first direction by the test device 100 (and/or the transport device 130), the electric circuit 110 accommodated in the frame 120 may come into contact the power supply device 200 located in the first direction of the test device 100, etc., but is not limited thereto.

In operation S930, the electric circuit 110 of the test device 100 and the subject 20 may be charged by the power supply device 200 while in electrical contact and/or electrical communication with the power supply device 200, etc. In operation S920, when the electric circuit 110 contacts and/or is in electrical communication with the power supply device 200, the charges from the power supply device 200 may charge the electric circuit 110 and/or the subject 20, etc.

In operation S940, the test device 100 may move the frame 120 in the second direction, but is not limited thereto. The test device 100 may move the frame 120 in the second direction as the controller 140 controls the transport device 130, etc.

In operation S950, the subject 20 may contact and/or may be in electrical communication with the host device 300, etc. In operation S940, as the frame 120 is moved in the second direction, the subject 20 accommodated in the frame 120 may contact and/or may be in electrical communication with the host device 300 located in the second direction of the test device 100, but is not limited thereto.

In operation S960, the electric circuit 110 of the test device 100 and/or the subject 20 may be discharged. More specifically, when the electric circuit 110 comes into contact and/or is in electrical communication with the host device 300, the charges stored in the electric circuit 110 and/or the subject 20 may be discharged towards the host device 300, etc.

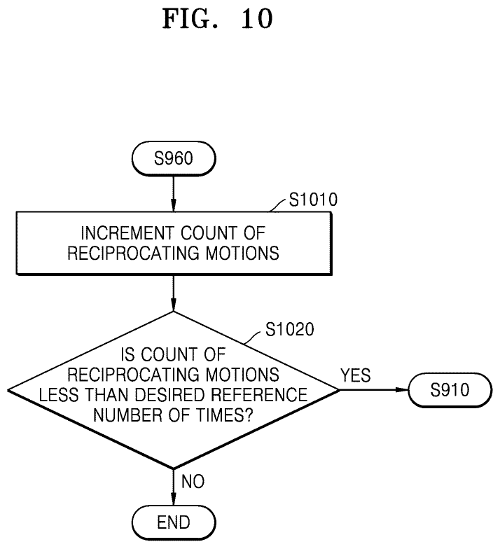

FIG. 10 is a flowchart of an additional method of operating a test device, according to at least one example embodiment.

Referring to FIG. 10, after operation S960 of FIG. 9 is completed, the controller 140 of the test device 100 may increase (e.g., increment, etc.) a count of the number of reciprocating motions performed by the test device 100 and/or the transport device 130 in operation S1010. The count of number of reciprocating motions may refer to the number of times that the test device 100 sequentially moves in the first direction and the second direction, but is not limited thereto, and for example, may refer to the number of times that the electric circuit 110 and/or the subject 20 is electrically connected to both the power supply device 200 and the host device 300, etc. That is, the count of the number of reciprocating motions may be the number of times that the test device 100 sequentially contacts the power supply device 200 and the host device 300, and may correspond to the number of times that the charges stored in the electric circuit 110 are discharged through the subject 20, etc. The controller 140 of the test device 100 may increase (e.g., increment, etc.) the count of the number of reciprocating motions by one when operations S910 to S960 of FIG. 9 are sequentially performed.

In operation S1020, the controller 140 of the test device 100 may determine whether the value of the count of the number of reciprocating motions is less than the desired and/or preset reference count.

When the count of the number of reciprocating motions is less than the reference count, this may indicate that the number of times that the charges charged to the electric circuit 110 are discharged through the subject 20 is less than the number of times that the user desires. Therefore, when the count of the number of reciprocating motions is less than the reference count, the controller 140 of the test device 100 may move to operation S910 and move the frame 120 in the first direction, etc., but is not limited thereto. Then, operations S920 to S960 may be sequentially performed again.

When the count of the number of reciprocating motions is not less than the reference count (e.g., the number of reciprocating motions is greater than or equal to the reference count), this may indicate that the number of times that the charges stored in the electric circuit 110 were discharged through the subject 20 corresponds to the number of times that the user desires. Therefore, when the count of the number of reciprocating motions is not less than the reference count, the controller 140 of the test device 100 may terminate the operations.

While some example embodiments of the inventive concepts have been particularly shown and described herein, it will be understood that various changes in form and details may be made therein without departing from the spirit and scope of the following claims.

What is claimed is:

1. A test device comprising:
an electrostatic discharge test circuit electrically connected to at least one subject;
a frame configured to accommodate the at least one subject and the electrostatic discharge test circuit;
a transport device configured to move, the movement of the transport device causing the frame to move; and
processing circuitry configured to,
control the movement of the transport device such that the electrostatic discharge test circuit becomes electrically connected to a power supply device based on a position of the transport device, and
control the movement of the transport device such that the at least one subject becomes electrically connected to a host device based on the position of the transport device.

2. The test device of claim 1, wherein the electrostatic discharge test circuit is further configured to:
store electrical charge received from the power supply device in response to the electrostatic discharge test circuit becoming electrically connected to the power supply device; and
in response to the electrostatic discharge test circuit becoming electrically connected to the host device through the at least one subject, discharging the stored electrical charges into the host device through the at least one subject.

3. The test device of claim 1, wherein
the electrostatic discharge test circuit includes a first discharge circuit; and
the first discharge circuit includes,
a first resistance circuit configured to electrically connect to the at least one subject; and
a first capacitor circuit configured to electrically connect to the first resistance circuit and a ground node.

4. The test device of claim 3, wherein the first discharge circuit is further configured to:
electrically connect to the power supply device through either a first node between the at least one subject and the first resistance circuit and a second node between the first resistance circuit and the first capacitor circuit.

5. The test device of claim 3, wherein
the electrostatic discharge test circuit further includes a second discharge circuit; and
the second discharge circuit includes,
a second resistance circuit configured to electrically connect to the at least one subject, and
a second capacitor circuit configured to electrically connect to the second resistance circuit and the ground node.

6. The test device of claim 5, wherein the second discharge circuit is further configured to:
electrically connect to the power supply device through either a third node between the at least one subject and the second resistance circuit and a fourth node between the second resistance circuit and the second capacitor circuit.

7. The test device of claim 1, wherein the electrostatic discharge test circuit is further configured to perform a simulation where static electricity is generated by a human body and discharged through the at least one subject based on a desired impedance value of the electrostatic discharge test circuit, the desired impedance value corresponding to an impedance value of a human model.

8. The test device of claim 1, wherein the processing circuitry is further configured to:
control the movement of the transport device to firstenable the electrostatic discharge test circuit to electrically connect to the power supply device, and second enable the at least one subject to electrically connect to the host device.

9. The test device of claim 1, wherein the processing circuitry is further configured to:
control the movement of the transport device such that the transport device moves between the power supply device and the host device a desired number of times.

10. A test system comprising:
an electrostatic discharge test circuit electrically connected to at least one subject;
a frame configured to accommodate the at least one subject and the electrostatic discharge test circuit;
a transport device configured to move, the movement of the transport device causing the frame to move;
processing circuitry configured to control the movement of the transport device;
a power supply device configured to selectively electrically connect to the electrostatic discharge test circuit based on a position of the transport device, the power supply device being configured to transfer electrical charge to the at least one subject and the electrostatic discharge test circuit; and
a host device configured to selectively electrically connect to the at least one subject based on the position of the transport device.

11. The test system of claim 10, wherein the electrostatic discharge test circuit is further configured to:
store the electrical charge from the power supply device in response to the electrostatic discharge test circuit becoming electrically connected to the power supply device; and
in response to the electrostatic discharge test circuit becoming electrically connected to the host device through the at least one subject, discharging the stored electrical charge into the host device through the at least one subject.

12. The test system of claim 10, wherein
the electrostatic discharge test circuit includes a first discharge circuit; and
the first discharge circuit includes,
a first resistance circuit configured to electrically connect to the at least one subject, and
a first capacitor circuit configured to electrically connect to the first resistance circuit and a ground node.

13. The test system of claim 12, wherein the first discharge circuit is further configured to:
electrically connect to the power supply device through either a first node between the at least one subject and the first resistance circuit and a second node between the first resistance circuit and the first capacitor circuit.

14. The test system of claim 12, wherein
the electrostatic discharge test circuit further includes a second discharge circuit; and
the second discharge circuit includes,
a second resistance circuit configured to electrically connect to the at least one subject; and
a second capacitor circuit configured to electrically connect to the second resistance circuit and the ground node.

15. The test system of claim 14, wherein the second discharge circuit is further configured to:
electrically connect to the power supply device through either a third node between the subject and the second resistance circuit and a fourth node between the second resistance circuit and the second capacitor circuit.

16. The test system of claim 10, wherein the electrostatic discharge test circuit is further configured to:
perform a simulation where static electricity is generated by a human body and discharged through the at least one subject based on a desired impedance value of the electrostatic discharge test circuit, the desired impedance value corresponding to an impedance value of a human model.

17. The test system of claim 10, wherein the processing circuitry is further configured to:
control the movement of the transport device to first enable the electrostatic discharge test circuit to electrically connect to the power supply device, and second enable the subject to electrically connect to the host device.

18. The test system of claim 10, wherein the processing circuitry is further configured to:
control the movement of the transport device to move between the power supply device and the host device for a desired number of times.

19. A method of operating a test device, the method comprising:
in response to at least one subject being accommodated in a frame and being electrically connected to an electrostatic discharge test circuit, moving the frame in a first direction using a transport device; and
moving the frame in a second direction using transport device.

20. The method of claim 19, further comprising:
incrementing a count of a number of reciprocating motions completed in response to the frame moving in the second direction; and
in response to the count of the number of reciprocating motions being less than a desired count value, moving the frame in the first direction using the transport device, and
moving the frame in the second direction using the transport device.
